(19) United States
(12) Patent Application Publication
(10) Pub. No.: US 2011/0265951 A1
(43) Pub. Date: Nov. 3, 2011

(54) TWIN CHAMBER PROCESSING SYSTEM

(75) Inventors: MING XU, San Jose, CA (US); ANDREW NGUYEN, San Jose, CA (US); EVANS LEE, Milpitas, CA (US); JARED AHMAD LEE, Santa Clara, CA (US); JAMES P. CRUSE, Santa Cruz, CA (US); CORIE LYNN COBB, Mountain View, CA (US); MARTIN JEFF SALINAS, San Jose, CA (US); ANCHEL SHEYNER, San Francisco, CA (US); EZRA ROBERT GOLD, Sunnyvale, CA (US); JOHN W. LANE, San Jose, CA (US)

(73) Assignee: APPLIED MATERIALS, INC., Santa Clara, CA (US)

(21) Appl. No.: 12/908,644

(22) Filed: Oct. 20, 2010

Related U.S. Application Data
(60) Provisional application No. 61/330,156, filed on Apr. 30, 2010.

(51) Int. Cl. C23F 1/08; C23C 16/458; C23C 16/52; C23C 16/455

(52) U.S. Cl. 156/345.26; 118/719; 118/712; 156/345.1; 156/345.33; 156/345.51

(57) ABSTRACT

Methods and apparatus for twin chamber processing systems are disclosed, and, in some embodiments, may include a first process chamber and a second process chamber having independent processing volumes and a plurality of shared resources between the first and second process chambers. In some embodiments, the shared resources include at least one of a shared vacuum pump, a shared gas panel, or a shared heat transfer source.

### CROSS-REFERENCE TO RELATED APPLICATIONS

This application claims benefit of U.S. provisional patent application Ser. No. 61/330,156, filed Apr. 30, 2010, which is herein incorporated by reference.

### FIELD

Embodiments of the present invention generally relate to substrate processing systems.

### BACKGROUND

Processing systems, for example, such as cluster tool having multiple process chambers on a shared transfer chamber are utilized to reduce system and manufacturing costs and improve process throughput. However, conventional process chambers are independently configured with the process resources necessary to facilitate performing the particular process therein. Such systems are costly to own and operate.

Therefore, the inventors have developed a twin chamber processing system having shared resources that can advantageously reduce system costs while simultaneously improving process throughput.

### SUMMARY

Methods and apparatus for a twin chamber processing system are disclosed herein. In some embodiments, one or more of a twin chamber processing system disclosed herein may be coupled to a transfer chamber. In some embodiments, a twin chamber processing system includes a first process chamber and a second process chamber having independent processing volumes and a plurality of shared resources between the first and second process chambers. In some embodiments, the shared resources include at least one of a shared vacuum pump, a shared gas panel, or a shared heat transfer source.

In some embodiments, a twin chamber processing system includes a first process chamber having a first vacuum pump for maintaining a first operating pressure in a first processing volume of the first process chamber and having a first substrate support disposed within the first process chamber, wherein the first processing volume can be selectively isolated by a first gate valve disposed between the first processing volume and a low pressure side of the first vacuum pump and wherein the first substrate support has one or more channels to circulate a heat transfer fluid to control a temperature of the first substrate support, a second process chamber having a second vacuum pump for maintaining a second operating pressure in a second processing volume of the second process chamber and having a second substrate support disposed within the second process chamber, wherein the second processing volume can be selectively isolated by a second gate valve disposed between the second processing volume and a low pressure side of the second vacuum pump and wherein the second substrate support has one or more channels to circulate the heat transfer fluid to control a temperature of the second substrate support, a shared vacuum pump coupled to the first and second processing volumes for reducing a pressure in each processing volume below a critical pressure level prior to opening the first and second gate valves, wherein the shared vacuum pump can be selectively isolated from any of the first process chamber, the second process chamber, the first vacuum pump, or the second vacuum pump, a shared gas panel coupled to each of the first process chamber and the second process chamber for providing one or more process gases to the first and second process chambers, and a shared heat transfer fluid source having an outlet to provide the heat transfer fluid to the respective one or more channels of the first substrate support and the second substrate support and an inlet to receive the heat transfer fluid from the first substrate support and the second substrate support.

Other and further embodiments of the present invention are described below.

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only typical embodiments of this invention and are therefore not to be considered limiting of its scope, for the invention may admit to other equally effective embodiments.

FIG. 1 depicts a schematic top view of a processing system in accordance with some embodiments of the present invention.

FIG. 2A depicts a schematic side view of a twin chamber processing system in accordance with some embodiments of the present invention.

FIG. 2B depicts a schematic side view of a twin chamber processing system in accordance with some embodiments of the present invention.

FIG. 3 depicts a schematic view of an exemplary gas distribution system in accordance with some embodiments of the present invention.

FIGS. 4A-C respectively depict partial schematic views of gas delivery zones coupled to the gas distribution system of FIG. 1 in accordance with some embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Methods and apparatus for a twin chamber processing system are disclosed herein. The inventive twin chamber processing system advantageously combines resources, for example, such as a shared vacuum pump, shared gas panel or the like, to reduce system costs while maintaining processing quality in each chamber of the twin chamber processing system. Further, the inventive methods advantageous control operation of chamber processes, such as reducing pressure, venting, purging or the like, when shared resources are used between each chamber of the twin chamber processing system.

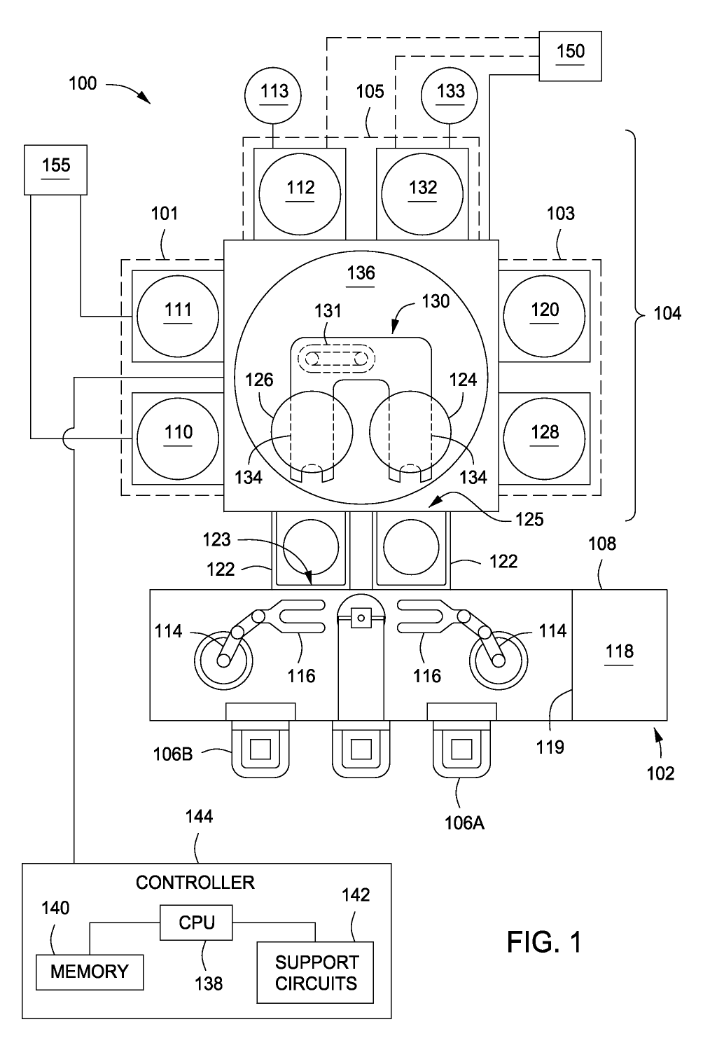

A twin chamber processing system disclosed herein may be part of a cluster tool having several twin chamber processing systems coupled thereto, for example, such as a processing system 100 illustrated in FIG. 1. Referring to FIG. 1, in some embodiments, the processing system 100 may generally comprise a vacuum-tight processing platform 104, a factory interface 102, one or more twin chamber processing systems 101, 103, 105 and a system controller 144. Examples of a processing system that may be suitably modified in accordance with the teachings provided herein include the CENTURA® integrated processing system, one of the PRODUCER® line of processing systems (such as the PRODUCER® GT™), ADVANTEDGE™ processing systems, commercially available from Applied Materials, Inc., located in Santa Clara, Calif. It is contemplated that other processing systems (including those from other manufacturers) may be adapted to benefit from the invention.

The platform 104 includes one or more twin chamber processing systems 101, 103, 105 (three shown in FIG. 1), each twin chamber processing system including two of process chambers (e.g., 110 and 111, 112 and 132, and 120 and 128). The platform further includes at least one load-lock chamber (two shown in FIG. 1) 122 that are coupled to a vacuum substrate transfer chamber 136. The factory interface 102 is coupled to the transfer chamber 136 via the load lock chambers 122.

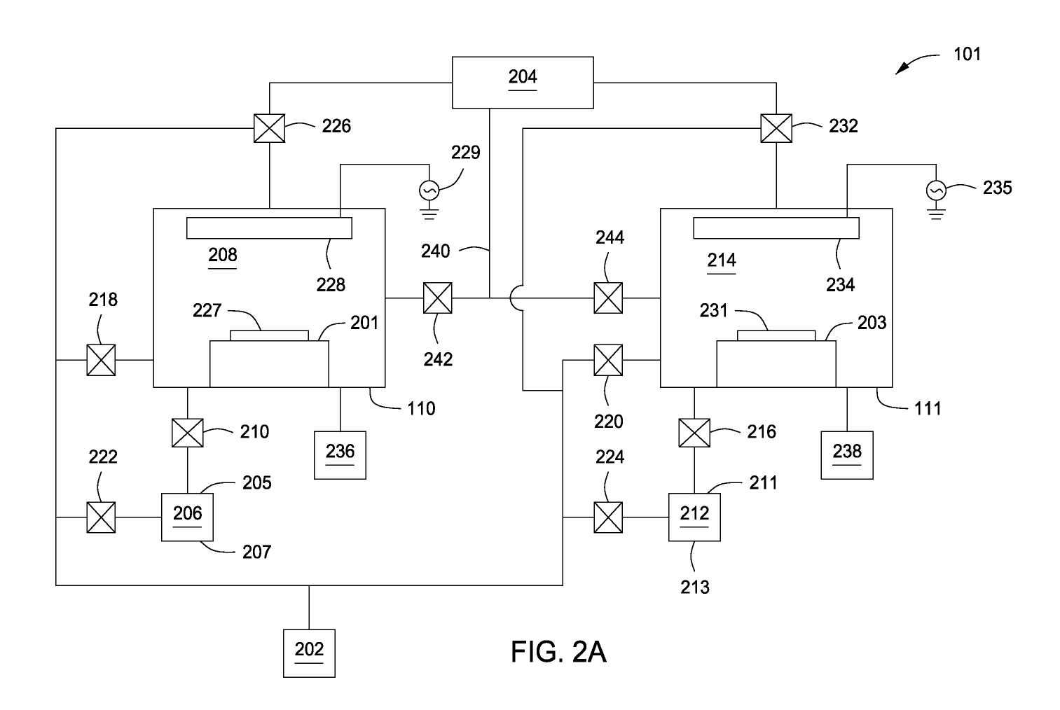

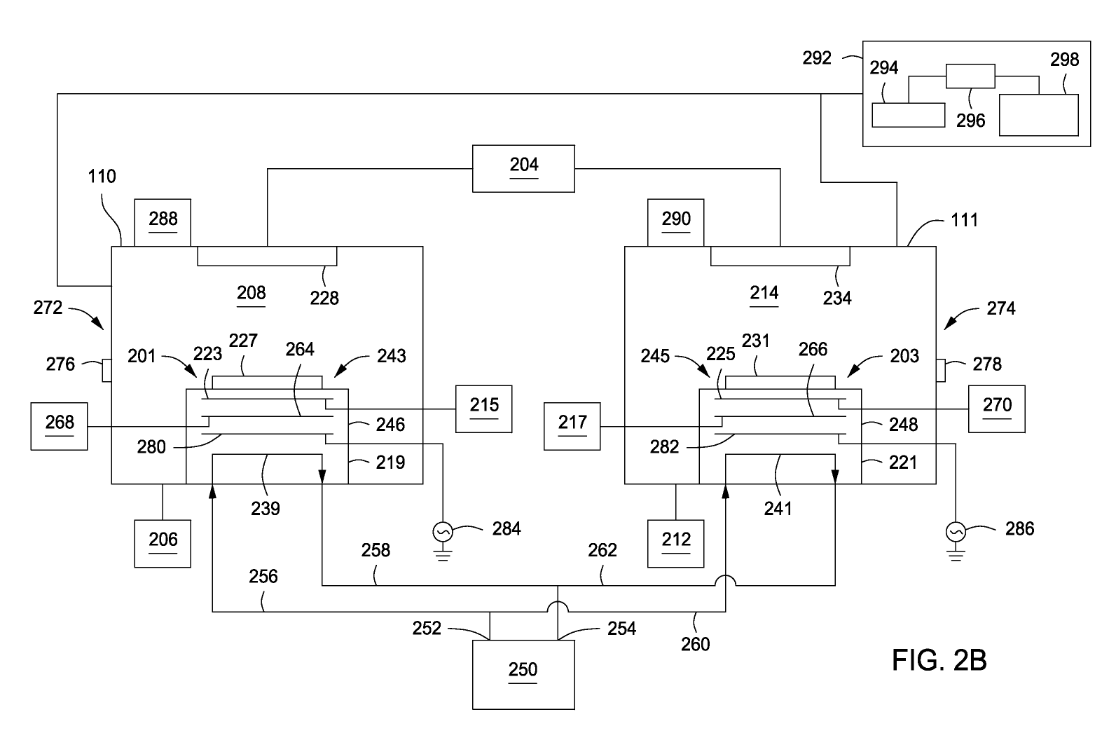

Each twin chamber processing system 101, 103, 105 includes independent processing volumes that may be isolated from each other. Each twin chamber processing system 101, 103, 105 may be configured to share resources (e.g., process gas supply, vacuum pump, heat transfer loops or the like) between each process chamber of the twin chamber processing system as discussed below and illustrated in FIGS. 2A-B and 3.

The factory interface 102 may comprise at least one docking station 108 and at least one factory interface robot (two shown in FIG. 1) 114 to facilitate transfer of substrates. The docking station 108 may be configured to accept one or more (two shown in FIG. 1) front opening unified pods (FOUPs) 106A-B. The factory interface robot 114 may comprise a blade 116 disposed on one end of the robot 114 configured to transfer the substrate from the factory interface 102 to the processing platform 104 for processing through the load lock chambers 122. Optionally, one or more metrology stations 118 may be connected to a terminal 119 of the factory interface 102 to facilitate measurement of the substrate from the FOUPs 106A-B.

Each of the load lock chambers 122 may include a first port 123 coupled to the factory interface 102 and a second port 125 coupled to the transfer chamber 136. The load lock chambers 122 may be coupled to a pressure control system (not shown) which pumps down and vents the load lock chambers 122 to facilitate passing the substrate between the vacuum environment of the transfer chamber 136 and the substantially ambient (e.g., atmospheric) environment of the factory interface 102. Embodiments of a suitable load lock chamber 122 that may be used with the twin chamber processing system are described in U.S. Provisional Patent Application Ser. No. 61/330,041, filed Apr. 30, 2010, by Jared Ahmad Lee, and entitled, “Apparatus For Radial Delivery Of Gas To A Chamber And Methods Of Use Thereof.”

The transfer chamber 136 has a vacuum robot 130 disposed therein. The vacuum robot 130 may have one or more transfer blades 134 (two shown in FIG. 1) coupled to a movable arm 131. For example, in some embodiments, where twin chamber processing systems are coupled to the transfer chamber 136 as shown, the vacuum robot 130 may have two parallel blades 134 configured such that the vacuum robot 130 may simultaneously transfer two substrates 124, 126 between the load lock chambers 122 and the process chambers of a twin chamber processing system, for example, process chambers 110, 111 of the twin chamber processing system 101.

The process chambers 110, 111 or 112, 132 or 120, 128 of each twin chamber processing system 101, 103, 105 may be any type of process chamber utilized in substrate processing, for example, such as etch chambers, deposition chambers, or the like. In some embodiments, the process chambers, for example process chambers 110, 111, of each twin chamber processing system, for example twin chamber processing system 101 are configured for the same function, for example, etching. For example, in embodiments where each process chamber of a twin chamber processing system is an etch chamber, each process chamber may include a plasma source, for example, an inductive or capacitively coupled plasma source, a remote plasma source or the like. Further, each process chamber of a twin chamber processing system may use a halogen-containing gas, for example, provided by a shared gas panel (as discussed below), to etch substrates (e.g., substrates 124, 126) disposed therein. Examples of halogen-containing gas include hydrogen bromide (HBr), chlorine (Cl₂), carbon tetrafluoride (CF₄), and the like. For example, after etching the substrates 124, 126, halogen-containing residues may remain on the substrate surface. The halogen-containing residues may be removed by a thermal treatment process in the load lock chambers 122, or by other suitable means.

Further the system 100 may include various apparatus that may be utilized to verify flow controllers, pressure gauges, or extend the lifetime of pressure gauges coupled to the either or both of the transfer chamber 136 and any one or more of the process chambers 110, 111, 112, 132, 120, 128. For example, a reference pressure gauge 150 may be selectively coupled to either or both of the transfer chamber 137 and the process chambers 110, 111, 112, 132, 120, 128 (only coupling to chambers 112, 132 is illustrated in FIG. 1). The reference pressure gauge 150 may be utilized to verify any one or more of individual pressure gauges coupled to each process chamber, such as pressure gauges 113, 133 coupled to process chambers 112, 132 respectively. Examples of suitable embodiments of methods and apparatus for calibrating pressure gauges that may be used in a substrate processing system, such as substrate processing system 100 are described in U.S. Provisional Patent Application Ser. No. 61/330,058, filed Apr. 30, 2010, by James P. Cruse, and entitled, “System And Method For Calibrating Pressure Gauges In A Substrate Processing System.” Examples of suitable methods and apparatus for extending the lifetime of pressure gauges, such as pressure gauges 113, 133, are described in U.S. Provisional Patent Application Ser. No. 61/330,027, filed Apr. 30, 2010, by James P. Cruse, and entitled, “Methods For Limiting The Lifetime Of Pressure Gauges Coupled To Substrate Process Chambers.”

Other apparatus that may be coupled to the either or both of the transfer chamber 136 and any one or more of the process chambers 110, 111, 112, 132, 120, 128 may include a mass flow verifier 155 for verifying flow from flow controllers, orifices or the like metering the flow of process gases to any one or more of the process chambers and transfer chamber 136. For example, the mass flow verifier 155 may be coupled the flow systems any of the twin chamber processing systems 101, 103, 105 or their individual chambers. The mass flow verifier 155 is illustrated in FIG. 1 as coupled to the process chambers 110, 111, however, this is merely for illustrative purposes and the mass flow verifier 155 may be coupled to all of the process chambers in the system 100. Examples of suitable embodiments of methods and apparatus for the mass flow verifier 155 are described in U.S. Provisional Patent Application Ser. No. 61/330,056, filed Apr. 30, 2010, by James P. Cruse, and entitled, “Methods And Apparatus For Calibrating Flow Controllers In Substrate Processing Systems.”

FIG. 2A depicts a schematic side view of a twin chamber processing system, for example twin chamber processing system 101, in accordance with some embodiments of the present invention. The twin chamber processing system 101 includes the process chambers 110, 111, wherein the process chambers 110, 111 share resources, for example, such as a shared vacuum pump 202 and a shared gas panel 204 as shown in FIG. 2A. In some embodiments, each twin chamber processing system coupled to the processing system 100 may be similarly configured.

The process chamber 110 (e.g., a first process chamber) has a first processing volume 208 that includes a first substrate support 201 disposed therein to support a first substrate 227. The process chamber 110 further includes a first vacuum pump 206 for maintaining a first operating pressure in the first processing volume 208. The first vacuum pump 206 may be, for example, a turbomolecular pump or the like. The first vacuum pump 206 may include a low pressure side 205 proximate the first processing volume 208 and a high pressure side 207 which may be selectively coupled to the shared vacuum pump 202 as discussed below. The first vacuum pump 206 may be selectively isolated from the first processing volume 208 by a first gate valve 210 disposed between the first processing volume 208 and the first vacuum pump 206, for example proximate the low pressure side 205 of the first vacuum pump 206.

The process chamber 111 (e.g., a second process chamber) of the twin chamber processing system 101 includes a second processing volume 214 having a second substrate support 203 disposed therein to support a second substrate 231. The process chamber 111 further includes a second vacuum pump 212 for maintaining a second operating pressure in the second processing volume 214. The second vacuum pump 212 may be, for example, a turbomolecular pump or the like. The second vacuum pump 212 may include a low pressure side 211 proximate the second processing volume 214 and a high pressure side 213 which may be selectively coupled to the shared vacuum pump 202 as discussed below. The second vacuum pump 212 may be selectively isolated from the second processing volume 214 by a second gate valve 216 disposed between the second processing volume 214 and the second vacuum pump 212, for example proximate the low pressure side 211 of the second vacuum pump 212.

The first and second processing volumes 208, 214 may be isolated from each other to facilitate substantially independent processing of substrates in each respective process chamber 110, 111. The isolated processing volumes of the process chambers within the twin chamber processing system advantageously reduces or eliminates processing problems that may arise due to multi-substrate processing systems where the processing volumes are fluidly coupled during processing. However, the twin chamber processing system further advantageously utilizes shared resources that facilitate reduced system footprint, hardware expense, utilities usage and cost, maintenance, and the like, while at the same time promoting higher substrate throughput. For example, shared hardware may include one or more of a process foreline and roughing pump, AC distribution and DC power supplies, cooling water distribution, chillers, multi-channel thermo controllers, gas panels, controllers, and the like.

The shared vacuum pump 202 may be coupled to any of the first and second processing volumes 208, 214 or the first and second vacuum pumps 206, 212 and selectively isolated therefrom. For example, the shared vacuum pump 202 may be coupled to the first and second processing volumes 208, 214 for reducing a pressure in each processing volume below a critical pressure level prior to opening the first and second gate valves 210, 216. For example, the critical pressure level may be a higher pressure than either of the first and second operating pressure provided by the first and second vacuum pumps 206, 212 respectively. However, the critical pressure level may be required for the first and second vacuum pumps 206, 212 to begin operation.

The shared vacuum pump 202 may be selectively coupled to the first processing volume 208 while bypassing the first vacuum pump 206 by a first roughing valve 218 disposed between the first processing volume 208 and the shared vacuum pump 202. For example, and as discussed in the methods below, the first vacuum pump 206 may be isolated from the first processing volume 208 by the first gate valve 210 while a pressure of the first processing volume 208 is lowered to below the critical pressure level, for example, suitable for operation of the first vacuum pump 206. Additional embodiments where the first vacuum pump 206 may be bypassed are also discussed below.

Similarly, the shared vacuum pump 202 may be selectively coupled to the second processing volume 214 while bypassing the second vacuum pump 212 by a second roughing valve 220 disposed between the second processing volume 214 and the shared vacuum pump 202. For example, and as discussed in the methods below, the second vacuum pump 212 may be isolated from the second processing volume 214 by the second gate valve 216 while a pressure of the second processing volume 214 is lowered to below the critical pressure level, for example, suitable for operation of the second vacuum pump 206. Additional method embodiments where the second vacuum pump 212 may be bypassed are also discussed below.

The shared vacuum pump 202 may be selectively coupled to the first vacuum pump 206 by a first isolation valve 222. For example, the first isolation valve 222 may be disposed between the high pressure 207 of the first vacuum pump 206 and the shared vacuum pump 202. In some embodiments, for example when the first vacuum pump 206 is in operation, the first isolation valve is open to allow gases or the like removed from the first processing volume 208 by the first vacuum pump 206 to be exhausted from the high pressure side 207 of the first vacuum pump 206 to the shared vacuum pump 202.

Similarly, the shared vacuum pump 202 may be selectively coupled to the second vacuum pump 212 by a second isolation valve 224. For example, the second isolation valve 224 may be disposed between the high pressure 213 of the second vacuum pump 212 and the shared vacuum pump 202. In some embodiments, for example when the second vacuum pump 212 is in operation, the second isolation valve is open to allow gases or the like removed from the second processing volume 214 by the second vacuum pump 212 to be exhausted from the high pressure side 213 of the second vacuum pump 212 to the shared vacuum pump 202.

The shared gas panel 204 may be coupled to each of the process chambers 110, 111 for providing one or more process gases to the first and second processing volumes 208, 214. For example, the shared gas panel may include one or more gases sources (not shown), for example where a gas from each gas source is metered out to each process chamber by one or more flow controllers, such as a mass flow controller, flow ratio controller or the like. Each gas source may be provided to each processing volume independently or to both processing volumes simultaneously, for example, to perform the same process in both process chambers 110, 111 simultaneously. As used herein, simultaneously means that the processes being performed in the two processing volumes at least partially overlap, begin after both substrates are delivered to the two processing volumes, and end prior to removal of either substrate from either of the two processing volumes.

A first three-way valve 226 can be disposed between the shared gas panel and the first processing volume 208 of the process chamber 110 to provide a process gas from the shared gas panel 204 to the first processing volume 208. For example, the process gas may enter the process chamber 110 at a first showerhead 228 or any suitable gas inlet(s) used for providing a process gas to a process chamber. Further, the first three-way valve 226 may divert the process gas from the shared gas panel 204 (e.g., bypassing the first processing volume 208) into a foreline conduit 230 coupled to the shared vacuum pump 202. Further, as shown, the foreline conduit 230 may couple the shared vacuum pump 202 to the high pressure side 207 of the first vacuum pump 206 and directly couple the shared vacuum pump 202 to the first processing volume 208.

The first showerhead 228 may include an electrode having a first RF power source 229 coupled thereto, for example, for striking a plasma in the first processing volume 208 from a process gas. Alternatively, the first RF power source 229 may be coupled to an electrode separate from the first showerhead 228 (not shown) or coupled to one or more inductive coils (not shown) disposed outside the first processing volume 208.

A second three-way valve 232 can be disposed between the shared gas panel and second processing volume 208 of the process chamber 111 to provide a process gas from the shared gas panel 204 to the second processing volume 208. For example, the process gas may enter the process chamber 111 at a second showerhead 234 or any suitable gas inlet(s) used for providing a process gas to a process chamber. Further, the second three-way valve 232 may divert the process gas from the shared gas panel 204 (e.g., bypassing the second processing volume 214) into the foreline conduit 230 coupled to the shared vacuum pump 202. Further, as shown, the foreline conduit 230 may couple the shared vacuum pump 202 to the high pressure side 213 of the second vacuum pump 212 and directly couple the shared vacuum pump 202 to the second processing volume 214.

The second showerhead 234 may include an electrode having a second RF power source 235 coupled thereto, for example, for striking a plasma in the second processing volume 214 from a process gas. Alternatively, the second RF power source 235 may be coupled to an electrode separate from the second showerhead 234 (not shown) or coupled to one or more inductive coils (not shown) disposed outside the second processing volume 214.

The first and second three-way valves 226, 232 may operate in response to a process endpoint detected, for example, by a first endpoint detector 236 for detecting the process endpoint in the process chamber 110 and by a second endpoint detector 238 for detecting the process endpoint in the process chamber 111. For example, a controller, for example such as the system controller 144 or a individual controller (not shown) coupled to one or more of the components of the twin chamber processing system 101, may be configured to receive a first signal from the first endpoint detector 236 when the process endpoint is reached in the process chamber 110 and to instruct the first three-way valve 226 to divert a process gas into the foreline conduit 230 if the process endpoint has not been reached in a process running in the process chamber 111. For example, although a process may be synchronized in each process chamber 110, 111 initially, the process may end at different times in each process chamber 110, 111 due to, for example, small variations in a substrate being processed, substrate temperature, plasma density or flux, or the like in each process chamber 110, 111. Similarly, the controller may be configured to receive a second signal form the second endpoint detector 238 when the process endpoint is reached in the process chamber 111 and to instruct the second three-way valve 232 to divert a process gas into the foreline conduit 230 if the process endpoint has not been reached in a process running in the process chamber 110.

Alternatively, and for example, the controller may, upon receiving the first signal from the first endpoint detector 236 that a process endpoint has been reached for a process being performed on a substrate in process chamber 110, turn off power to the RF power source 229 to terminate a plasma in the first processing volume 208. Further, the process gas may continue to flow into the first processing volume 208 after the RF power source 229 is turned off instead of being diverted by the three-way valve 226 when the process endpoint is reached. A similar alternative embodiment upon receiving the second signal from the second endpoint detector 238 may be performed in process chamber 111. Further, if a signal is received from either of the first or second endpoint detectors 236, 238, the controller may, in some embodiments, terminate the processes in both chambers regardless of whether the process endpoint is detected in both chambers. For example, if the first signal is received from the first endpoint detector 236 that a process endpoint has been reached in the process chamber 110, the controller may terminate the processes in both chambers 110, 111 even though the second signal has not been received from the second endpoint detector 238. Alternatively, if the first signal is received signaling a process endpoint has been reached in the process chamber 110, the controller may not take any action in either process chamber 110, 111 until the second signal is received signaling a process endpoint has been reached in the process chamber 111 as well.

Alternatively, a process need not be precisely synchronized in both process chambers 110, 111 and for example may begin in each chamber when a substrate has reached the appropriate process temperature or another similar process condition. Accordingly, when a process endpoint is reach in a given chamber, the process gas is diverted by a three-way valve into the foreline conduit 230 until the process endpoint is reached in the adjacent chamber prior to removing the substrates from the chambers 110, 111 or prior to beginning a further processing step. Further embodiments to methods of synchronization and/or endpoint detection in twin chamber processing systems are described in U.S. Provisional Patent Application Ser. No. 61/330,021, filed Apr. 30, 2010, by James P. Cruse, and entitled, “Methods For Processing Substrates In Process Systems Having Shared Resources.”

The shared gas panel may further provide a gas for purging the process chambers 110, 111. For example, a vent line 240 may be selectively coupled to each of the first and second processing volumes 208, 214 either directly (as shown) or via the high pressure sides 207, 213 of respective first and second vacuum pumps 206, 212 (not shown). For example, the purge gas may include nitrogen (N₂), argon (Ar), helium (He), or the like. The purge gas may be selectively provided to the first processing volume 208 via a first purge valve 242 disposed between the shared gas panel 204 and the first processing volume 208. Similarly, the purge gas may be selectively provided to the second processing volume 214 via a second purge valve 244 disposed between the shared gas panel 204 and the second processing volume 214. Further, in applications where the purge gas is utilized to vent each process chamber 110, 111 to atmosphere, a vent (not shown), for example such as a valve or the like, may be provided for each chamber 110, 111 such that each chamber 110, 111 may be vented to atmosphere independently from the other chamber.

Returning to FIG. 1, the system controller 144 is coupled to the processing system 100. The system controller 144 controls the operation of the system 100 using a direct control of the process chambers 110, 111, 112, 132, 128, 120 of the system 100 or alternatively, by controlling individual controllers (not shown) associated with the process chambers 110, 111, 112, 132, 128, 120 and/or each twin chamber processing system 101, 103, 105 and the system 100. In operation, the system controller 144 enables data collection and feedback from the respective chambers and system controller 144 to optimize performance of the system 100.

The system controller 144 generally includes a central processing unit (CPU) 138, a memory 140, and support circuit 142. The CPU 138 may be one of any form of a general purpose computer processor that can be used in an industrial setting. The support circuits 142 are conventionally coupled to the CPU 138 and may comprise cache, clock circuits, input/output subsystems, power supplies, and the like. The software routines, such as a method 300, 400, or 500 described below for controlling one or more chamber processes, such as reducing pressure, venting or purging each chamber of a twin chamber processing system, when executed by the CPU 138, transform the CPU 138 into a specific purpose computer (controller) 144. The software routines may also be stored and/or executed by a second controller (not shown) that is located remotely from the system 100.

Methods for controlling various chamber processes of the process chambers of a twin chamber processing system, such as the twin chamber processing system 101 depicted in FIG. 2, are described in U.S. Provisional Patent Application Ser. No. 61/330,105, filed Apr. 30, 2010, by Ming Xu, and entitled, “Twin Chamber Processing System With Shared Vacuum Pump.”

### Shared Heat Transfer Fluid Source in a Twin Chamber Processing System

Embodiments of a shared heat transfer fluid source in a twin chamber processing system are described below and depicted in FIG. 2B. The embodiments illustrated in FIGS. 2A-2B can be incorporated into one twin chamber processing system, for example, including a shared vacuum pump and gas panel (FIG. 2A) and a shared heat transfer source (FIG. 2B). For the purposes of simplicity of illustration, the shared vacuum pump and gas panel (FIG. 2A) and the shared heat transfer source (FIG. 2B) are illustrated separately. Where appropriate common numbering is used in each of FIGS. 2A-2B and may be used to describe the same element in each of FIGS. 2A-2B.

FIG. 2B depicts two exemplary process chambers 110, 111 suitable for use in conjunction with one or more shared resources in accordance with some embodiments of the present invention. The process chambers 110, 111 may be any type of process chamber, for example, such as the process chambers described above with respect to FIG. 1. Each of the process chambers 110, 111 may be the same type of process chamber, and in some embodiments, may be part of a twin chamber processing system (such as the twin chamber processing system 101 shown in FIG. 1). In some embodiments, each process chamber is an etch chamber and is part of a twin chamber processing system.

In some embodiments, each process chamber 110, 111 may generally comprise a chamber body defining an inner volume that may include a processing volume 208, 214. The processing volume 208, 214 may be defined, for example, between a substrate support pedestal 201, 203 disposed within the process chamber 110, 111 for supporting a substrate 227, 231 thereupon during processing and one or more gas inlets, such as a showerhead 228, 234 and/or nozzles provided at desired locations.

In some embodiments, the substrate support pedestal 201, 203 may include a mechanism that retains or supports the substrate 227, 231 on the surface 243, 245 of the substrate support pedestal 201, 203, such as an electrostatic chuck, a vacuum chuck, a substrate retaining clamp, or the like. For example, in some embodiments, the substrate support pedestal 203, 205 may include a chucking electrode 223, 225 disposed within an electrostatic chuck 246, 248. The chucking electrode 223, 225 may be coupled to one or more chucking power sources (one chucking power source 215, 217 per chamber shown) through one or more respective matching networks (not shown). The one or more chucking power source 215, 217 may be capable of producing up to 12,000 W at a frequency of about 2 MHz, or about 13.56 MHz, or about 60 Mhz. In some embodiments, the one or more chucking power source 215, 217 may provide either continuous or pulsed power. In some embodiments, the chucking power source may be a DC or pulsed DC source.

In some embodiments, the substrate support 201, 203 may include one or more mechanisms for controlling the temperature of the substrate support surface 243, 245 and the substrate 227, 231 disposed thereon. For example, one or more channels 239, 241 may be provided to define one or more flow paths beneath the substrate support surface 243, 245 to flow a heat transfer fluid. The one or more channels 239, 241 may be configured in any manner suitable to provide adequate control over temperature profile across the substrate support surface 243, 245 and the substrate 227, 231 disposed thereon during processing. In some embodiments, the one or more channels 239, 241 may be disposed within a cooling plate 219, 221. In some embodiments, the cooling plate 219, 221 may be disposed beneath the electrostatic chuck 246, 248.

The heat transfer fluid may comprise any fluid suitable to provide adequate transfer of heat to or from the substrate 227, 231. For example, the heat transfer fluid may be a gas, such as helium (He), oxygen (O₂), or the like, or a liquid, such as water, antifreeze, or an alcohol, for example, glycerol, ethylene glycerol, propylene, methanol, or the like.

A shared heat transfer fluid source 250 may simultaneously supply the one or more channels 239, 241 of each process chamber 110, 111 with the heat transfer fluid. In some embodiments, the shared heat transfer fluid source 250 may be coupled to each process chamber 110, 111 in parallel. For example, the shared heat transfer fluid source 250 comprises at least one outlet 252 coupled to one or more supply conduits (one per chamber shown) 256, 260 to provide the heat transfer fluid to the one or more channels 239, 241 of each of the respective process chambers 110, 111. In some embodiments, each of the supply conduits 256, 260 may have a substantially similar fluid conductance. As used herein, substantially similar fluid conductance means within +/−10 percent. For example, in some embodiments, each of the supply conduits 256, 260 may have a substantially similar cross sectional area and axial length, thereby providing a substantially similar fluid conductance. Alternatively, in some embodiments, each of the supply conduits 256, 260 may comprise different dimensions, for example such as a different cross sectional area and/or axial length, thereby each providing a different fluid conductance. In such embodiments, different dimensions of each of the supply conduits 256, 260 may provide different flow rates of heat transfer fluid to each of the one or more channels 239, 241 of each of the process chambers 110, 111.

Additionally, the shared heat transfer fluid source 250 comprises at least one inlet 254 coupled to one or more return conduits (one per chamber shown) 258, 262 to receive the heat transfer fluid from the one or more channels 239, 241 of each of the respective process chambers 110, 111. In some embodiments, each of the supply return conduits 258, 262 may have a substantially similar fluid conductance. For example, in some embodiments, each of the return conduits 258, 262 may comprise a substantially similar cross sectional area and axial length. Alternatively, in some embodiments, each of the return conduits 258, 262 may comprise different dimensions, for example such as a different cross sectional area and/or axial length.

The shared heat transfer fluid source 250 may include a temperature control mechanism, for example a chiller and/or heater, to control the temperature of the heat transfer fluid. One or more valves or other flow control devices (not shown) may be provided between the heat transfer fluid source 250 and the one or more channels 239, 241 to independently control a rate of flow of the heat transfer fluid to each of the process chambers 110, 111. A controller (not shown) may control the operation of the one or more valves and/or of the shared heat transfer fluid source 250.

In operation, the shared heat transfer fluid source 250 may provide a heat transfer fluid at a predetermined temperature to each of the one or more channels 239, 241 of each of the process chambers 110, 111 via the supply conduits 256, 260. As the heat transfer fluid flows through the one or more channels 239, 241 of the substrate support 201, 203, the heat transfer fluid either provides heat to, or removes heat from the substrate support 201, 203, and therefore the substrate support surface 243, 245 and the substrate 227, 231 disposed thereon. The heat transfer fluid then flows from the one or more channels 239, 241 back to the shared heat transfer fluid source 250 via the return conduits 258, 262, where the heat transfer fluid is heated or cooled to the predetermined temperature via the temperature control mechanism of the shared heat transfer fluid source 250.

In some embodiments, one or more heaters (one per chamber shown) 264, 266 may be disposed proximate the substrate support 201, 203 to further facilitate control over the temperature of the substrate support surface 243, 245. The one or more heaters 264, 266 may be any type of heater suitable to provide control over the substrate temperature. For example, the one or more heaters 264, 266 may be one or more resistive heaters. In such embodiments, the one or more heaters 264, 266 may be coupled to a power source 268, 270 configured to provide the one or more heaters 264, 266 with power to facilitate heating the one or more heaters 264, 266. In some embodiments the heaters may be disposed above or proximate to the substrate support surface 243, 245. Alternatively, or in combination, in some embodiments, the heaters may be embedded within the substrate support 201, 203 or the electrostatic chuck 246, 248. The number and arrangement of the one or more heaters may be varied to provide additional control over the temperature of the substrate 227, 231. For example, in embodiments where more than one heater is utilized, the heaters may be arranged in a plurality of zones to facilitate control over the temperature across the substrate 227, 231, thus providing increased temperature control.

The substrate 227, 231 may enter the process chamber 110, 111 via an opening 272, 274 in a wall of the process chamber 110, 111. The opening 272, 274 may be selectively sealed via a slit valve 276, 278, or other mechanism for selectively providing access to the interior of the chamber through the opening 272, 274. The substrate support pedestal 201, 203 may be coupled to a lift mechanism (not shown) that may control the position of the substrate support pedestal 201, 203 between a lower position suitable for transferring substrates into and out of the chamber via the opening 272, 274 and a selectable upper position suitable for processing. The process position may be selected to maximize process uniformity for a particular process. When in at least one of the elevated processing positions, the substrate support pedestal 201, 203 may be disposed above the opening 272, 274 to provide a symmetrical processing region.

The one or more gas inlets (e.g., the showerhead 228, 234) may be coupled to independent or a shared gas supply (shared gas supply 204 shown) for providing one or more process gases into the processing volume 208, 214 of the process chambers 110, 111. Although a showerhead 228, 234 is shown in FIG. 2B, additional or alternative gas inlets may be provided such as nozzles or inlets disposed in the ceiling or on the sidewalls of the process chambers 110, 111 or at other locations suitable for providing gases as desired to the process chambers 110, 111, such as the base of the process chamber, the periphery of the substrate support pedestal, or the like.

In some embodiments, the process chambers 110, 111 may utilize capacitively coupled RF power for plasma processing, although the process chambers 110, 111 may also or alternatively use inductive coupling of RF power for plasma processing. For example, the substrate support 201, 203 may have an electrode 280, 282 disposed therein, or a conductive portion of the substrate support 201, 203 may be used as the electrode. The electrode may be coupled to one or more plasma power sources (one RF power source 284, 286 per process chamber shown) through one or more respective matching networks (not shown). In some embodiments, for example where the substrate support 201, 203 is fabricated from a conductive material (e.g., a metal such as aluminum) the entire substrate support 201, 203 may function as an electrode, thereby eliminating the need for a separate electrode 280, 282. The one or more plasma power sources may be capable of producing up to about 5,000 W at a frequency of about 2 MHz and or about 13.56 MHz or high frequency, such as 27 MHz and/or 60 MHz.

In some embodiments, endpoint detection systems 288, 290 may be coupled to each of the process chambers 110, 111 and used to determine when a desired endpoint of a process is reached in each chamber. For example, the endpoint detection system 288, 290 may be one or more of an optical spectrometer, a mass spectrometer, or any suitable detection system for determining the endpoint of a process being performed within the processing volume 208, 214. In some embodiments, the endpoint detection system 288, 290 may be coupled to a controller 292 of the process chambers 110, 111. Although a single controller 292 is shown for the process chambers 110, 111 (as may be used in a twin chamber processing system), individual controllers may alternatively be used for each process chamber 110, 111. Alternatively, the controller 144 (discussed above with respect to FIG. 1), or some other controller, may also be used.

The vacuum pump 206, 212 may be coupled to the pumping plenum via a pumping port for pumping out the exhaust gases from the process chambers 110, 111. The vacuum pump 206, 212 may be fluidly coupled to an exhaust outlet for routing the exhaust as required to appropriate exhaust handling equipment. A valve, such as a gate valve or the like (for example, the gate valves 210, 216 shown in FIG. 2A), may be disposed in the pumping plenum to facilitate control of the flow rate of the exhaust gases in combination with the operation of the vacuum pump 206, 212 (shared vacuum pump 202 and related apparatus, such as gate valve 210, 216, is omitted from FIG. 2B for clarity).

To facilitate control of the process chambers 110, 111, the controller 292 may be one of any form of general-purpose computer processor that can be used in an industrial setting for controlling various chambers and sub-processors. The memory, or computer-readable medium, 294 of the CPU 296 may be one or more of readily available memory such as random access memory (RAM), read only memory (ROM), floppy disk, hard disk, or any other form of digital storage, local or remote. The support circuits 298 are coupled to the CPU 296 for supporting the processor in a conventional manner. These circuits include cache, power supplies, clock circuits, input/output circuitry and subsystems, and the like. Further embodiments of methods and apparatus associated with a shared heat transfer source are described in U.S. Provisional Patent Application Ser. No. 61/330,014, filed Apr. 30, 2010, by Jared Ahmad Lee, and entitled, “Process Chambers Having Shared Resources And Methods Of Use Thereof.”

### Gas Distribution System for a Twin Chamber Processing System

Embodiments of the present invention provide a gas distribution system that passively divides a gas flowing therethrough in to desired flow ratio. The apparatus is based on the fundamental principle that flow through an orifice is directly proportional to the cross-sectional area. If a gas stream is split between two orifices where one is twice as large (in cross-sectional area) as the other, the ratio of the flows will be two to one. However, this principle is dependent on both orifices having the same upstream and downstream pressures. In the present invention, different gas delivery zones coupled to the apparatus (e.g., zones of a showerhead, different process chambers, or the like) may have different conductance, or resistance to flow and, thus, the downstream pressures may not be the same. In some embodiments, the inventors have eliminated this issue by designing the apparatus to always operate in a choked flow condition (e.g., the upstream pressure is at least twice the downstream pressure). If flow is choked, then the flow will only be a function of the upstream pressure.

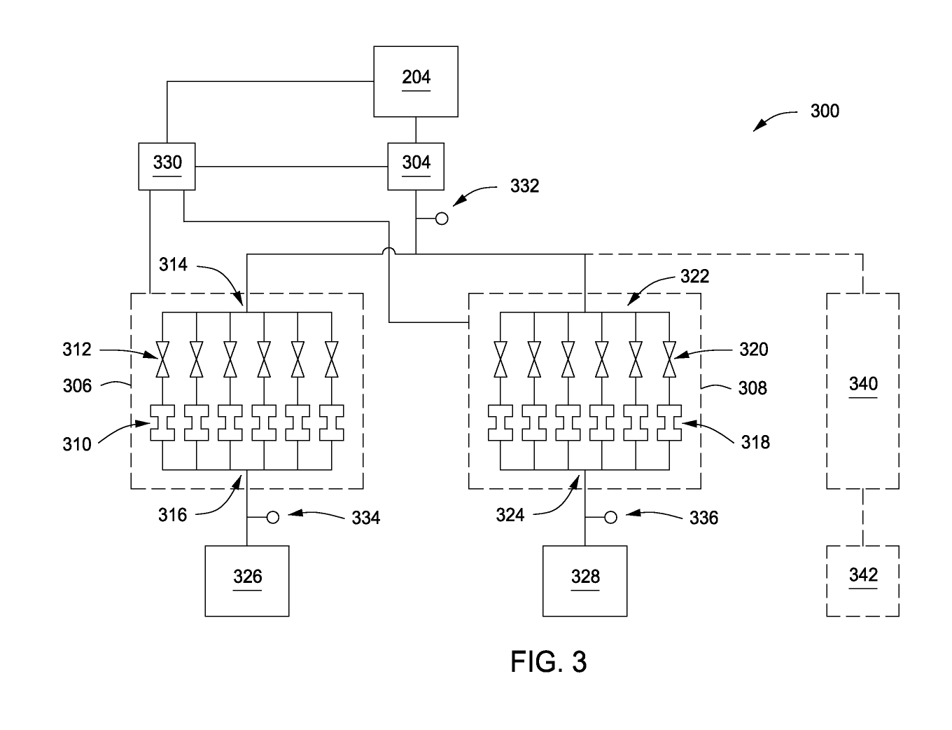

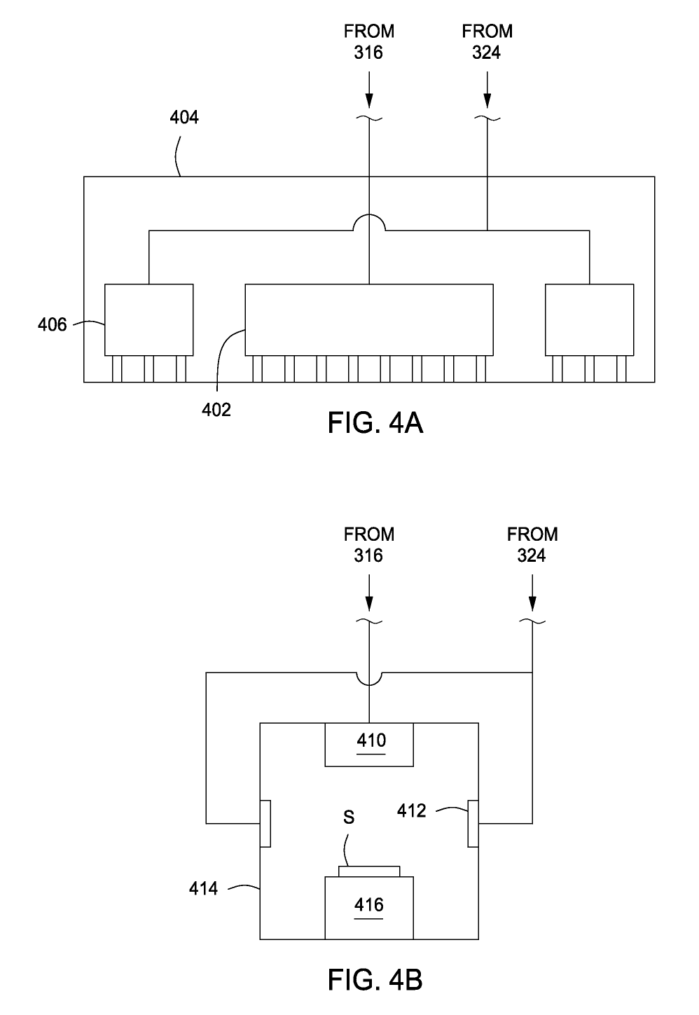

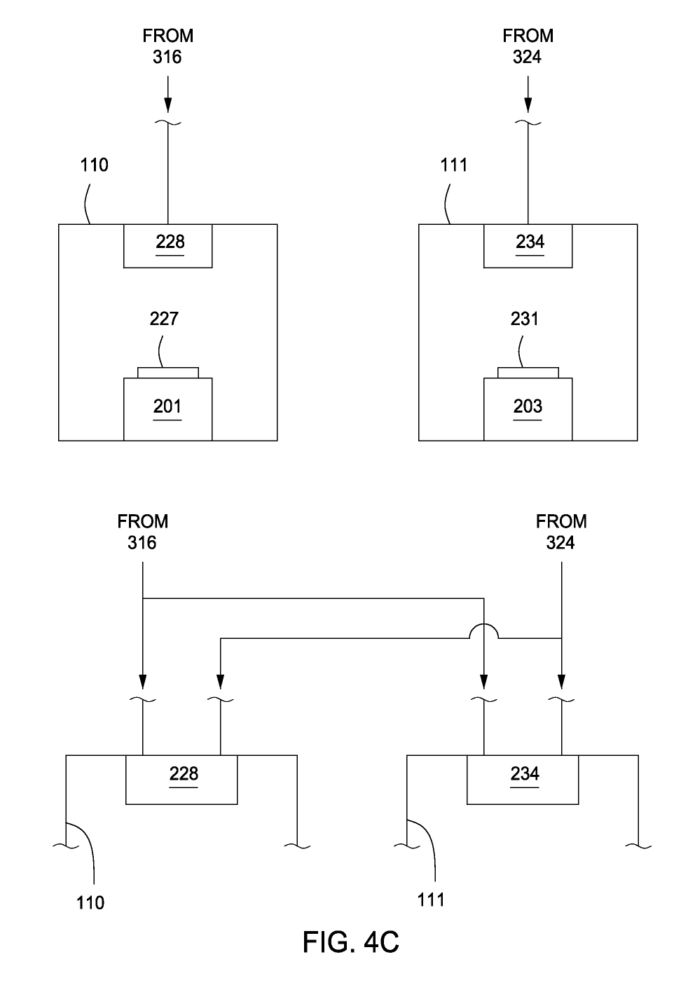

Similar to FIGS. 2A-2B above, FIGS. 3-4 may use common numbering to describe elements in FIG. 3 which are substantially the same as discussed above with respect to FIGS. 1 and 2A-B. FIG. 3 depicts a schematic view of an exemplary gas distribution system 300 in accordance with some embodiments of the present invention. Although the system depicted in FIG. 3 primarily relates to providing a gas flow to two gas delivery zones (e.g., 326, 328), the system may be expanded in accordance with the principles disclosed herein to providing the gas flow to additional gas delivery zones (e.g., 342, as shown in phantom). The gas distribution system 300 generally includes one or more mass flow controllers (one mass flow controller 304 shown), a first flow control manifold 306, and a second flow control manifold 308 (additional flow control manifolds, similarly configured as described herein, may be provided, as shown by reference numeral 340 in phantom). The mass flow controller 304 is typically coupled to a gas distribution panel 204 that provides one or more gases or gaseous mixtures (referred to throughout and in the claims as a gas). The mass flow controller 304 controls the total flow rate of the gas through the gas distribution apparatus 300 and is coupled to both of the first and second flow control manifolds 306, 308 at respective inlets thereof. Although one mass flow controller 304 is shown, a plurality of mass flow controllers may be coupled to the gas distribution panel 204 to meter respective process gases from the gas distribution panel 204. The outputs of the one or more mass flow controllers 304 are generally coupled (e.g., fed into a common conduit, mixer, plenum, or the like, or combinations thereof) prior to being split and routed to each flow control manifold (e.g., 306, 308).

The first flow control manifold 306 includes a plurality of first orifices 310 and a plurality of first control valves 312 coupled between an inlet 314 and an outlet 316 of the first flow control manifold 306. The plurality of first control valves 312 may be selectively opened or closed in order to selectively couple one or more of the plurality of first orifices 310 to the outlet of the mass flow controller 304 (e.g., to allow the gas to flow from the mass flow controller 104 through the selected first orifices 310).

Similarly, the second flow control manifold 308 includes a plurality of second orifices 318 and a plurality of second control valves 320 coupled between an inlet 322 and an outlet 324 of the second flow control manifold 308. The plurality of second control valves 320 may be selectively opened or closed in order to selectively couple one or more of the plurality of second orifices 318 to the mass flow controller 304 (e.g., to allow the gas to flow through the selected second orifices 318). Similarly additional flow control manifolds (such as 340) may be provided to provide a gas in a desired flow ratio to additional gas delivery zones (such as 342).

The first and second control valves 312, 320 may be any suitable control valves for use in a industrial environment, or in a semiconductor fabrication environment. In some embodiments, the first and second control valves 312, 320 may be pneumatically actuated valves. In some embodiments, the first and second control valves 312, 320 may be mounted on a substrate (not shown) where the seals for each control valve had a precision orifice built into the structure of the seal. In some embodiments, the orifices may be built into the body of the control valves. In some embodiments, separate control valves and orifices may be provided.

In the embodiment depicted in FIG. 1, six first orifices 310 and six second orifices 318 are shown, each coupled to respective first control valves 312, and respective second control valves 320. However, each flow control manifold does not need to have the same number of orifices—although having the same number and configuration of orifices facilitates ease of providing the same flow ratios between the first and second gas delivery zones 326, 328 regardless of whether the ratio is between the first and the second gas delivery zones 326, 328 or between the second and the first gas delivery zones 328, 326. In addition, each zone may have a fewer or greater number of orifices than six. Generally speaking, fewer orifices allows fewer flow ratios to be provided, and more orifices allow more flow ratios to be provided, but at greater cost and complexity. As such, the number of orifices provided may be selected based upon the desired processing flexibility required for a particular application.

The configuration of the gas distribution system 300 may be determined based upon the anticipated operating conditions and output requirements for a particular application. For example, in some embodiments, the gas distribution system 100 may provide flow ratios between 1:1 and 6:1 in half ratio increments (i.e., 1/1, 1.5/1, 2/1, 2.5/1 . . . 6/1) and must be fully reversible (i.e., 1/1, 1/1.5, 2/1, 2.5/1 . . . 1/6) between the gas delivery zones 326, 328. In some embodiments, the accuracy of the gas flow split may be within 5 percent, for example, to match the performance of existing equipment. In some embodiments, the gas distribution system 100 may be designed to ratio properly for a gas flow between 50 and 500 sccm nitrogen equivalent per gas delivery zone 326, 328 and is compatible with all process gases. In some embodiments, the upstream pressure (or back pressure) of the gas distribution system 300 may be minimized to reduce the response time of the gas distribution system 300. In addition, the upstream pressure (or back pressure) of the gas distribution system 300 may be restricted or minimized to prevent the undesirable condensation of some low vapor pressure gases (for example, silicon tetrachloride, SiCl₄). As such, in some embodiments, the restricted upstream pressure is low enough to prevent condensation of low vapor pressure gases. For example, the first and second flow control manifolds may provide a pressure drop sufficient to maintain choked flow while minimizing the pressure upstream of the orifice(s) to prevent condensation of any semiconductor process chemistries whose vapor pressure at the use temperature could approach the pressure upstream of the orifice. Low vapor pressure gases include gases that leave the gas phase (i.e., liquefy) at the operating pressure and temperature. Non-limiting examples include about 150 Torr for SiCl₄, about 100 Torr for C₆F₆, about 5 psig for C₄F₈, and the like. In some embodiments, the maximum allowable restricted upstream pressure was designed to be the vapor pressure of SiCl₄ at room temperature, or 155 Torr.

Typically, the upstream pressure may be minimized to minimize response time of the system. For example, at a given flow rate, the volume between the flow controller and the orifice will take some period of time to reach a desired pressure and provide steady state flow. Thus, higher pressures will require a longer period of time to fill this volume to the higher pressure and thus take longer to achieve steady state flow. In some embodiments, the volume between the flow controller and the orifices may be minimized to minimize response time. However, in some embodiments, the restricted upstream pressure may be controlled to optimize the response time of the system, for example, to control to a specific response time to match other systems. As such, in some embodiments, the first and second flow control manifolds may provide a pressure drop sufficient to maintain choked flow while controlling the pressure upstream of the orifice(s) to control the response time of the system. Such control may be provided, for example, by controlling the volume between the flow controller and the orifices, by intentionally selecting more restrictive orifices to create higher back pressures, or the like. Different applications and/or processes may have different desired response times (e.g., optimized response times) based upon the specific process being performed (e.g., etching, chemical vapor deposition, atomic layer deposition, physical vapor deposition, or the like). In some embodiments, the desired response time may be 2 seconds or less, or 5 seconds or less, or 10 seconds or less, or 15 seconds or less.

In some embodiments, flow modeling software (such as Macroflow) may be used to select the desired sizes of the first and second orifice 310, 318 for each of the first and second flow control manifolds 306, 308 in order to meet the requirements for etch processing. For example, in some embodiments, this may be determined by finding the largest orifice that will still yield choked flow for the minimum desired process gas flow. In some embodiments, 6 orifices per zone may be provided with increments in orifice size of 1, 1.5, 2, 4, 8, and 12 (e.g., multiplication factors). In some embodiments, the smallest orifice diameter may be 0.0090″ (for example, to provide choked flow at a smallest desired flow) and all orifice diameters are multiples of the smallest orifice diameter. In some embodiments, the orifice diameters may be 0.009, 0.011, 0.013, 0.018, 0.025, and 0.031 inch. Orifices having these diameters are commercially available orifice diameters, and may be selected rather than diameters that would provide exact ratios of cross-sectional area in order to provide a more cost-effective solution where repeatability and reproducibility are more important than exact ratios. For example, the modeling showed that with this configuration, all ratios and all flows between 10 and 1200 sccm nitrogen equivalent per zone could meet both the choked flow and maximum back pressure requirements.

In some embodiments, using the orifice diameters described above, the gas delivery system 300 may be capable of providing a gas flow of from about 16 sccm to about 2300 sccm at a 1:1 flow ratio, and a gas flow of from about 40 sccm to about 1750 sccm at a 4:1 flow ratio. These flow rate ranges are expressed in terms of nitrogen equivalent gas flow, as discussed in more detail below.

The outlets 316, 324 of the first and second flow control manifolds 306, 308 may be respectively coupled to a first gas delivery zone 326 and a second gas delivery zone 328. Each gas delivery zone 326, 328 may thus receive a desired percentage of the total gas flow provided by the mass flow controller 104 based upon a desired flow ratio imposed by the selective coupling of the first orifices 310 and the second orifices 318. The gas delivery zones 326, 328 may generally be any zones where control over the gas flow ratio is desired.

For example, in some embodiments, and as shown in FIG. 4A, the first gas delivery zone 326 may correspond to a first zone 402, such as an inner zone, of a showerhead 404 for providing the gas to a process chamber in which the showerhead 404 is installed. The second gas delivery zone 328 may correspond to a second zone 406, such as an outer zone, of the showerhead 404.

In some embodiments, as shown in FIG. 4B, the first and second gas delivery zones 326, 328 may be respectively provided to a showerhead 410 and one or more gas inlets 412 of a process chamber 414 having a substrate support 416 for supporting a substrate S thereon.

In some embodiments, as shown in the upper portion of FIG. 4C, the first and second gas delivery zones 326, 328 may be respectively provided to the showerheads 228, 234 (and/or other gas inlets) of the process chambers 110, 111 having the substrate supports 201, 203 for supporting respective substrates 227, 231 thereon. Alternatively, and shown in the lower portion of FIG. 4C, the first and second gas delivery zones 326, 328 may be provided to both showerheads 228, 234 (and/or other gas inlets) of different process chambers 110, 111. For example, the first gas delivery zone 326 may correspond to a first zone (such as first zone 402 of showerhead 404 as depicted in FIG. 4A) in each showerhead 228,234 and the second gas delivery zone 328 may correspond to a second zone (such as second zone 406 of showerhead 404 as depicted in FIG. 4A) in each showerhead 228, 234.

Further, although not shown in FIG. 4C, the first and second gas delivery zones 326, 328 need not be limited to being provided to two showerheads, and may be provided to any suitable plurality of showerheads in a plurality of process chambers. For example, the first gas delivery zone 326 may correspond to a first zone in a plurality of showerheads of a plurality of process chambers and the second gas delivery zone 328 may correspond to a second zone in a plurality of showerheads of a plurality of process chambers.

Returning to FIG. 3, one or more pressure gauges may be provided to monitor the pressure at desired locations of the gas distribution apparatus 100. For example, a pressure gauge 332 may be provided to monitor the upstream pressure of the gas distribution apparatus 300. In some embodiments, the pressure gauge 332 may be disposed in a gas line coupled between the mass flow controller 304 and the first and second flow control manifolds 306, 308. Pressure gauges 334, 336 may be provided to respectively monitor the downstream pressure of the gas distribution apparatus 300. In some embodiments, the pressure gauges 334, 336 may be respectively disposed in gas lines respectively coupled between the first and second flow control manifolds 306, 308 and the first and second gas delivery zones 326, 328.

A controller 330 may be provided and coupled to the gas distribution system 300 for controlling the components of the system. For example, the controller 330 may be coupled to the gas distribution panel 204 to select one or more process gases to provide, the mass flow controller 304 to set a desired flow rate, and to each of the first and second flow control manifolds 306, 308 (or to each of the first and second control valves 312, 320 contained therein) to control which control valves 312, 320 to open in order to provide the desired flow ratio. The controller may further be coupled to the pressure gauges 332, 334, 336 in order to ensure that the pressure requirements are being met for choked flow and minimized back pressure.

The controller 330 may be any suitable controller and may be the process controller for a process chamber or process tool to which the gas distribution system 100 is coupled, or some other controller. The controller 330 generally includes a central processing unit (CPU), a memory, and support circuits. The CPU may be one of any form of a general purpose computer processor that can be used in an industrial setting. The support circuits are coupled to the CPU and may comprise cache, clock circuits, input/output subsystems, power supplies, and the like. Software routines, such as the methods for operating the gas distribution system 300 described herein, for example with respect to FIGS. 3-4, may be stored in the memory of the controller 330. The software routines, when executed by the CPU, transform the CPU into a specific purpose computer (controller) 330. The software routines may also be stored and/or executed by a second controller (not shown) that is located remotely from the controller 330. Alternatively, similar to embodiments discussed above, the gas distribution system 330 may be controlled by the controller 144 (FIG. 1) or any of the other controllers discussed above.

Embodiments of the gas distribution system 300 were tested by the inventors over a range of desired flow ratios, several flow rates, and using multiple gases. The gas distribution system 300 met all accuracy requirements for etch processing at gas flows of 50 to 500 sccm. The repeatability of the gas distribution system 300 was found to be within 1 percent. Further embodiments of methods and apparatus associated with the gas distribution system 300 are described in U.S. Provisional Patent Application Ser. No. 61/330,047, filed Apr. 30, 2010, by James P. Cruse, and entitled, “Methods And Apparatus For Reducing Flow Splitting Errors Using Orifice Ratio Conductance Control.”

Thus, methods and apparatus for a twin chamber processing system have been provided. The inventive twin chamber processing system advantageously combines resources, for example, such as a shared vacuum pump, shared gas panel or the like, to reduce system costs while maintaining processing quality in each chamber of the twin chamber processing system. Further, the inventive methods advantageous control operation of chamber processes, such as reducing pressure, venting, purging or the like, when shared resources are used between each chamber of the twin chamber processing system.

While the foregoing is directed to embodiments of the present invention, other and further embodiments of the invention may be devised without departing from the basic scope thereof.

1. A twin chamber processing system for processing substrates, comprising:
a first process chamber having a first vacuum pump for maintaining a first operating pressure in a first processing volume of the first process chamber, wherein the first processing volume can be selectively isolated by a first gate valve disposed between the first processing volume and a low pressure side of the first vacuum pump;
a second process chamber having a second vacuum pump for maintaining a second operating pressure in a second processing volume of the second process chamber, wherein the second processing volume can be selectively isolated by a second gate valve disposed between the second processing volume and a low pressure side of the second vacuum pump;
a shared vacuum pump coupled to the first and second processing volumes for reducing a pressure in each processing volume below a critical pressure level prior, wherein the shared vacuum pump can be selectively isolated from any of the first process chamber, the second process chamber, the first vacuum pump, or the second vacuum pump; and
a shared gas panel coupled to each of the first process chamber and the second process chamber for providing one or more process gases to the first and second process chambers.

2. The twin chamber processing system of claim 1, further comprising:
a first three-way valve disposed between the shared gas panel and the first process chamber to provide a process gas from the shared gas panel to the first processing volume of the first process chamber or to divert the process gas from the shared gas panel into a foreline conduit coupled to the shared vacuum pump; and
a second three-way valve disposed between the shared gas panel and the second process chamber to provide the process gas from the shared gas panel to the second processing volume of the second process chamber or to divert the process gas from the shared gas panel into a foreline conduit coupled to the shared vacuum pump.

3. The twin chamber processing system of claim 1, further comprising:
a mass flow controller to provide a desired total gas flow from the shared gas panel to the first and second process chambers;
a first flow control manifold comprising a first inlet, a first outlet, and a plurality of first orifices selectably coupled therebetween, wherein the first inlet is coupled to the mass flow controller; and
a second flow control manifold comprising a second inlet, a second outlet, and a plurality of second orifices selectably coupled therebetween, wherein the second inlet is coupled to the mass flow controller;
wherein the plurality of first orifices and the plurality of second orifices provide a desired flow ratio between the first outlet and the second outlet by selectably causing the fluid to flow through one or more of the plurality of first orifices and one or more of the plurality of second orifices and wherein the conductance of a conduit provided between the mass flow controller and the respective inlets of the first and second flow control manifolds is sufficient to provide a choked flow condition when flowing a gas through the apparatus.

4. The twin chamber processing system of claim 3, wherein the first outlet is coupled to a first gas delivery zone of a first process chamber and the second outlet is coupled to a second gas delivery zone of the first process chamber.

5. The twin chamber processing system of claim 4, wherein the first outlet is further coupled to a first gas delivery zone of a second process chamber and the second outlet is further coupled to a second gas delivery zone of the second process chamber.

6. The twin chamber processing system of claim 1, further comprising:
a first substrate support disposed within the first process chamber, wherein the first substrate support has one or more channels to circulate a heat transfer fluid to control a temperature of the first substrate support;
a second substrate support disposed within the second process chamber, wherein the second substrate support has one or more channels to circulate the heat transfer fluid to control a temperature of the second substrate support; and
a shared heat transfer fluid source having an outlet to provide the heat transfer fluid to the respective one or more channels of the first substrate support and the second substrate support and an inlet to receive the heat transfer fluid from the first substrate support and the second substrate support.

7. A twin chamber substrate processing system, comprising:
a first process chamber having a first vacuum pump for maintaining a first operating pressure in a first processing volume of the first process chamber and having a first substrate support disposed within the first process chamber, wherein the first processing volume can be selectively isolated by a first gate valve disposed between the first processing volume and a low pressure side of the first vacuum pump and wherein the first substrate support has one or more channels to circulate a heat transfer fluid to control a temperature of the first substrate support;
a second process chamber having a second vacuum pump for maintaining a second operating pressure in a second processing volume of the second process chamber and having a second substrate support disposed within the second process chamber, wherein the second processing volume can be selectively isolated by a second gate valve disposed between the second processing volume and a low pressure side of the second vacuum pump and wherein the second substrate support has one or more channels to circulate the heat transfer fluid to control a temperature of the second substrate support;
a shared vacuum pump coupled to the first and second processing volumes for reducing a pressure in each processing volume below a critical pressure level, wherein the shared vacuum pump can be selectively isolated from any of the first process chamber, the second process chamber, the first vacuum pump, or the second vacuum pump;
a shared gas panel coupled to each of the first process chamber and the second process chamber for providing one or more process gases to the first and second process chambers; and
a shared heat transfer fluid source having an outlet to provide the heat transfer fluid to the respective one or more channels of the first substrate support and the second substrate support and an inlet to receive the heat transfer fluid from the first substrate support and the second substrate support.

8. The twin chamber processing system of claim 7, further comprising:
a transfer chamber having a plurality of twin chamber processing systems as described in claim 7 coupled thereto.

9. The twin chamber processing system of claim 8, further comprising:
a mass flow verifier selectively fluidly coupled to each process chamber of the plurality of twin process chambers to verify and calibrate respective mass flow meters coupled to each process chamber.

10. The twin chamber processing system of claim 9, further comprising:
a reference pressure gauge selectively fluidly coupled to each process chamber of the plurality of twin process chambers to verify and calibrate respective pressure gauges coupled to each process chamber.

11. A twin chamber processing system for processing substrates, comprising:
a first process chamber and a second process chamber disposed in a common housing, the first process chamber having a first processing volume and the second process chamber having a second processing volume, wherein the first and second processing volumes can be isolated from each other during processing;
a shared vacuum pump coupled to the first and second processing volumes for reducing a pressure in each processing volume;
a shared gas panel coupled to each of the first process chamber and the second process chamber for providing one or more process gases to the first and second process chambers; and
a shared heat transfer fluid source having an outlet to provide the heat transfer fluid to respective one or more channels of a first substrate support disposed in the first process chamber and a second substrate support disposed in the second process chamber, and an inlet to receive the heat transfer fluid from the first substrate support and the second substrate support.

12. The twin chamber processing system of claim 11, further comprising:
a mass flow controller to provide a desired total gas flow from the shared gas panel to the first and second process chambers;
a first flow control manifold comprising a first inlet, a first outlet, and a plurality of first orifices selectably coupled therebetween, wherein the first inlet is coupled to the mass flow controller; and
a second flow control manifold comprising a second inlet, a second outlet, and a plurality of second orifices selectably coupled therebetween, wherein the second inlet is coupled to the mass flow controller;
wherein the plurality of first orifices and the plurality of second orifices provide a desired flow ratio between the first outlet and the second outlet by selectably causing the fluid to flow through one or more of the plurality of first orifices and one or more of the plurality of second orifices and wherein the conductance of a conduit provided between the mass flow controller and the respective inlets of the first and second flow control manifolds is sufficient to provide a choked flow condition when flowing a gas through the apparatus.

13. The twin chamber processing system of claim 11, wherein the first outlet is coupled to a first gas delivery zone of a first process chamber and the second outlet is coupled to a second gas delivery zone of the first process chamber.

14. The twin chamber processing system of claim 13, wherein the first outlet is further coupled to a first gas delivery zone of a second process chamber and the second outlet is further coupled to a second gas delivery zone of the second process chamber.

15. The twin chamber processing system of claim 11, further comprising:
a transfer chamber having a plurality of twin chamber processing systems as described in claim 11 coupled thereto.

16. The twin chamber processing system of claim 15, further comprising:
a mass flow verifier selectively fluidly coupled to each process chamber of the plurality of twin process chambers to verify and calibrate respective mass flow meters coupled to each process chamber.

17. The twin chamber processing system of claim 16, further comprising:
a reference pressure gauge selectively fluidly coupled to each process chamber of the plurality of twin process chambers to verify and calibrate respective pressure gauges coupled to each process chamber.
